(19) United States
(12) Patent Application Publication
(10) Pub. No.: US 2012/0045864 A1
(43) Pub. Date: Feb. 23, 2012

(54) MULTILAYER FILM FORMATION METHOD AND FILM DEPOSITION APPARATUS USED WITH THE METHOD

(75) Inventor: Takehito WADA, Funabashi city (JP)

(73) Assignee: FUJI ELECTRIC CO., LTD., Kawasaki-shi (JP)

(21) Appl. No.: 13/212,571

(22) Filed: Aug. 18, 2011

(30) Foreign Application Priority Data
Aug. 19, 2010 (JP) 2010-183974

(51) Int. Cl. H01L 21/20; C23C 16/458; C23C 16/52; C23C 16/455

(52) U.S. Cl. 438/62; 118/719; 257/E21.09

(57) ABSTRACT

A multilayer film formation method and film deposition apparatus that suppress fluctuations in thickness, stabilize product quality, and reduce costs. The method employs gas-phase chemical reaction to form a multilayer film having at least three layers using raw material gases of differing compositions. A film formation apparatus is provided having at least first and second film deposition portions along a transfer path of the substrate, and having a supply/recovery portion for the substrate at either end of the transfer path; continuously transferring the substrate along the transfer path at a first speed during a first transfer and film deposition to form a plurality of stacked layers including first and second layers; and continuously transferring the substrate along the transfer path at a second speed during a second transfer and film deposition to form a third layer having the third composition that differs from those of the first and second layers.

### CROSS-REFERENCE TO RELATED APPLICATION(S)

This non-provisional Application claims the benefit of the priority of Applicant's earlier-filed Japanese Patent Application Laid-open No. 2010-183974, filed Aug. 19, 2010, the entire contents of which are incorporated herein by reference.

### BACKGROUND OF THE INVENTION

1. Field of the Invention

The present invention relates to a multilayer film formation method, and more particularly, relates to a multilayer film formation method for a thin film photovoltaic conversion element, or the like, including a multiple of layers of differing thickness, and to a film deposition apparatus used with the method.

2. Background of the Related Art

As a manufacturing method of a thin film photovoltaic conversion element, there is a heretofore known method whereby a multilayer film including a photovoltaic conversion layer, with non-crystalline silicon as a main material, is formed on a substrate. Although it is often the case that a sheet substrate such as a glass substrate is used as the substrate, there are also cases in which an elongated, band-like flexible substrate formed from a plastic film or metal thin plate is used.

As a configuration of a film deposition apparatus, there is a configuration wherein a substrate (a sheet substrate) is gripped with a robot arm installed in a common chamber, conveyed to a film deposition chamber disposed on the periphery thereof, and a film deposition carried out, or a configuration (an in-line type) wherein plural film deposition chambers or film deposition regions are installed along a transfer path of a substrate (a sheet substrate or elongated substrate), and a film deposition is carried out while the substrate is transferred. Although the freedom in processing of the latter in-line type is low in comparison with the former type, it is superior in that time needed for transferring is reduced.

Included within in-line types of film deposition apparatus, there is a stepped film deposition type wherein the substrate is transferred intermittently at a predetermined pitch, and film deposition is carried out while the transferring is stopped, and a continuous film deposition type wherein film deposition is carried out while the substrate is continuously transferred at a predetermined speed.

With the stepped film deposition type of film deposition apparatus, a mixing of gases between film deposition regions is suppressed by making the film deposition chambers an open/close type or installing a gate valve, or the like, between the film deposition chambers, as shown in, for example, JP-A-11-145060, and as it is possible to individually control the film deposition time in each film deposition region, this type is suited to a multilayer film formation including plural layers with differing film quality or thickness. The installation of a gas gate between film deposition chambers is disclosed in Japanese Patent No. 3,255,903. However, in addition to the expense entailed by installation of these sealing structures, it is necessary to provide film deposition chambers in accordance with the number of layers to be formed so that the size of the apparatus increases.

Meanwhile, with the continuous film deposition type of film deposition apparatus, high productivity is obtained when depositing layers with a uniform film quality and thickness because there is no need to set transfer time and film deposition time separately. However, with a multilayer film formation including plural layers with differing film quality or thickness, it is necessary to interchange raw material gases and carry out a film deposition for each layer and, in order to suppress the diffusion of impurities, it is necessary to implement a remaining gas removal step separately from the film deposition step when interchanging gases, as described in JP-A-10-22518 and JP-A-2000-183380.

Moreover, as the thickness of the layers to be formed depends on the film deposition time and the film deposition time is determined by the transfer speed, it is necessary to change the transfer speed in accordance with the thickness (the film deposition time) of each layer. That is, it is necessary to carry out a film deposition at a relatively fast transfer speed for a thin layer and to carry out a film deposition at a relatively slow transfer speed for a thick layer. In this case, particularly with a multilayer film formation including plural layers with differing film quality or thickness, such as with a thin film photovoltaic cell, it is necessary to adopt a wide range of varying transfer speeds, and the apparatus cost increases. Although there exist various kinds of speed control methods that make the motor rotation speed variable in order to make the transfer speed variable, in many cases, the accuracy of the speed control depends on the motor rotation speed. For this reason, when the transfer speed variation range increases, the transfer speed control accuracy decreases commensurately, fluctuations in thickness increase, and there is also a risk of product characteristics deteriorating.

### SUMMARY OF THE INVENTION

The invention, having been contrived bearing in mind the heretofore described known technology, has an object of providing a multilayer film formation method and film deposition apparatus used with the method that suppress thickness fluctuation in a multilayer film including a multiple of layers of differing thickness, and that can stabilize product quality and reduce device and manufacturing costs.

In order to achieve the heretofore described object, the inventor obtained the following findings and, after careful consideration, devised the invention. It is often the case that a multilayer film including a multiple of layers of differing film quality and thickness is configured of basic layers determining the function of the film and additional layers (interface layers or the like) added as necessary between the basic layers, wherein the additional layers are normally thinner than the basic layers, and it is often the case that the compositions of raw material gases between adjacent layers are similar. Although the previously described technical difficulties with multilayer film formation are caused by this kind of variation in film quality or thickness, (a) with the additional layers, the intrinsic function of the multilayer film is not impaired even in the event of an interdiffusion of gas, provided that it is an extremely small amount, occurring between adjacent layers, and (b) effects on the intrinsic function due to this kind of slight amount of interdiffusion may be sufficiently outweighed by an improvement in product quality owing to the equalization of film deposition conditions.

That is, a first aspect of the invention employs a multilayer film formation method that employs gas-phase chemical reaction to form three or more layers with raw material gases of differing compositions on at least one surface of a substrate, the method including providing a film formation apparatus having at least first and second film deposition portions along a transfer path of the substrate, and having a supply/recovery portion for the substrate at either end of the transfer path; continuously transferring the substrate along the transfer path at a first speed during a first transfer and film deposition while simultaneously supplying first and second raw material gases with mutually similar compositions respectively to each of the first and second film deposition portions to form a plurality of stacked layers including first and second layers with mutually similar compositions; and continuously transferring the substrate along the transfer path at a second speed during a second transfer and film deposition, before or after the first transfer and film deposition, while supplying third raw material gases having a composition that differs from those of the first and second raw material gases, and whose compositions are essentially the same as each other, to each of the first and second film deposition portions, to form a third layer having a composition that differs from those of the first and second layers.

With the multilayer film formation method according to the first aspect of the invention, by plural layers including the first and second layers being sequentially formed by being stacked on the substrate by simultaneously forming stacked layers (the plural layers including the first and second layers) with mutually similar raw material gas compositions in the first transfer and film deposition step, while the third layer with a raw material gas composition differing from those of the first and second layers is formed in the separate second transfer and film deposition step, as heretofore described, it is possible to reduce the difference between a first speed (the transfer speed of the first transfer and film deposition step) and a second speed (the transfer speed of the second transfer and film deposition step), that is, the transfer speed variation range, and it is possible to reduce the apparatus cost, in comparison with a case in which the film deposition time and transfer speed are equalized for each transfer and film deposition step, and each of a first layer, second layer, and third layer are deposited individually. Also, by reducing the transfer speed variation range, the transfer speed control accuracy is improved, and it is possible to stabilize product quality items such as thickness or film quality. Furthermore, it does not happen that the scale of the film deposition apparatus becomes overly large, as in the case of feeding the substrate in intermittent steps and sequentially depositing the layers during each period of stopping, and also, it is possible to reduce the number of transfer and film deposition steps in comparison with the case of individually depositing each layer, the frequency of the gas interchange step between transfer and film deposition steps and the operating frequency of the substrate supply/recovery portions in the transfer path end portions are reduced, and there is also an advantage in that the manufacturing process is simplified.

In light of the above premise, it is advantageous for the multilayer film formation method according to the first aspect of the invention that the third layer has a thickness that is greater than the combined thickness of a plurality of layers including the first and second layers. It is advantageous, taking versatility and manufacturing cost into consideration, that electrode pairs that carry out a gas-phase chemical reaction are installed in each of the first and second film deposition portions and are configured to the same specifications, and with that kind of device configuration, by the deposition of the third layer having a large thickness being implemented using each of the first and second film deposition portions, it is possible to improve the film deposition processing efficiency (e.g., when the electrode area is two times larger, the transfer speed can be made two times faster, and the film deposition time can be reduced by half).

In light of the same kind of premise, it is advantageous for the multilayer film formation method according to the first aspect of the invention that the third layer have a thickness that is at least two times greater than the combined thickness of a plurality of layers including the first and second layers, and the second transfer and film deposition for forming the third layer is implemented divided into plural times. There is no need to expand the transfer speed variation range, even when the difference in thickness is large, and it is possible to implement film deposition steps of a stable quality. In this case, although the number of transfer and film deposition steps increases by the number of times the second transfer and film deposition step is divided, there is no need for a gas interchange step between the transfer and film deposition steps, and it does not happen that the manufacturing process becomes troublesome.

With the multilayer film formation method according to the first aspect of the invention, a case is assumed wherein the first and second raw material gases include added constituents common to each other which differ in amounts, while the third raw material gases do not include the added constituents. Alternatively, a case is assumed wherein the first and second raw material gases are such that the concentration of the main gas of each differs, and only the layer farther from the third layer includes added constituents, while the third raw material gases do not include the added constituents.

The multilayer film formation method according to the first aspect of the invention can be particularly preferably implemented in a case in which the multilayer film is a thin film photovoltaic conversion element having a p-i-n junction structure, the first and second layers are a p-type semiconductor layer and p/i interface layer or an n-type semiconductor layer and n/i interface layer, and the third layer is an i-type semiconductor layer.

In a thin film photovoltaic conversion element having a p-i-n junction structure, the thickness of an i-type semiconductor layer forming a power generation layer is greater than the thickness of another p-type semiconductor layer and n-type semiconductor layer, and is greater than the combined thickness of the p-type semiconductor layer, n-type semiconductor layer, and a p/i interface layer and n/i interface layer adjacent to the p-type semiconductor layer and n-type semiconductor layer. Also, the p/i interface layer and n/i interface layer have raw material gas compositions near those of the respectively adjacent p-type semiconductor layer and n-type semiconductor layer. Consequently, by simultaneously forming stacked the p-type semiconductor layer and p/i interface layer, and n-type semiconductor layer and n/i interface layer, in one transfer and film deposition step each, and forming the thicker i-type semiconductor layer in a separate transfer and film deposition step using both the first and second film deposition portions, it is possible, owing to a synergistic effect whereby the transfer speed (the first speed) when depositing the p-type semiconductor layer, p/i interface layer, n-type semiconductor layer, and n/i interface layer, which have a smaller thickness, is halved, and the transfer speed (the second speed) when depositing the thicker i-type semiconductor layer increases two-fold, to reduce the transfer speed variation range (the difference between the first speed and second speed) to an extremely narrow range, even when the difference in thickness between the i-type semiconductor layer and each other layer is eight times or more.

Also, the multilayer film formation method according to the first aspect of the invention can be particularly preferably implemented in a case in which the multilayer film is a thin film photovoltaic conversion element having a p-i-n junction structure, the first and second layers are a p-type semiconductor layer and p/i interface layer or an n-type semiconductor layer and n/i interface layer, the added constituent is a doping gas corresponding to each type, and the third layer is an i-type semiconductor layer.

Although extremely small, there is a tolerance range for the concentration setting of the doping gas corresponding to each of the p and n-types between the p-type semiconductor layer and p/i interface layer adjacent thereto, and between the n-type semiconductor layer and n/i interface layer adjacent thereto, and advantages derived from an improvement in control accuracy owing to the equalization of film deposition conditions, and from the accompanying uniformity of film distribution, outweigh the fluctuation of the concentration setting within this kind of tolerance range.

The multilayer film formation method according to the first aspect of the invention is particularly preferable when including implementing plural transfer and film deposition steps, including the first and second transfer and film deposition steps, while reciprocally transferring the substrate between the supply/recovery portions at either end of the transfer path. As heretofore described, as the film deposition time and transfer speed are equalized for each transfer and film deposition step, and the transfer speed variation range is small, the multilayer film formation method according to the first aspect of the invention is best suited to film deposition while reciprocally transferring the substrate.

With the multilayer film formation method according to the first aspect of the invention, it is preferable that the step of preparing the film deposition apparatus includes preparing a film deposition apparatus having, as the first and second film deposition portions, first and second film deposition chambers in communication with each other via slits through which the substrate can pass, and inside each of which at least one film deposition electrode pair is arranged in parallel. According to this configuration, as the diffusion of gas between the film deposition portions is suppressed even when disposing the film deposition portions adjacently along the transfer path, and the conductance is reduced, it is possible to implement good film depositions steps.

Furthermore, with the multilayer film formation method according to the first aspect of the invention, it is preferable that the step of preparing the film deposition apparatus includes preparing a film deposition apparatus in which at least two film deposition electrode pairs are arranged in parallel inside at least one of the first and second film deposition chambers. With this configuration, other than the case in which the first layer and second layer are allotted to the first and second film deposition chambers, it is possible to simultaneously form still more layers by allotting each electrode pair in the film deposition chambers to a layer adjacent to the first layer or second layer and with a similar composition, for example, each type of second interface layer or each type of second semiconductor layer, and also, by changing the distribution of the electrode pairs allotted to the first layer and second layer, it is also possible to respond to a case in which the first layer and second layer are of differing thickness.

The heretofore described kind of advantage is also obtained when the step of preparing the film deposition apparatus includes preparing a film deposition apparatus having, as the first and second film deposition portions, at least two film deposition electrode pairs arranged in parallel inside a common vacuum chamber. However, the conditions for the combinations of raw material gases with which simultaneous film deposition is possible are strict in comparison with the case of including plural film deposition chambers in communication with each other via slits.

That is, even in a case in which two or more film deposition portions forming separate films are adjacent, as the configuration is such that film depositions using similar gases are adjacent, as in the configuration according to the first aspect of the invention, film deposition is possible even with no boundary, but the film quality of each layer is better with adjacent film deposition chambers in communication with each other via slits.

With the multilayer film formation method according to the first aspect of the invention, it is particularly preferable that, the substrate is a band-like substrate, the step of providing the film deposition apparatus includes preparing a film deposition apparatus having unwinding/winding portions for the substrate as the supply/recovery portions, and each of the transfer and film deposition steps includes unwinding the substrate from a roll in one unwinding/winding portion, and winding a substrate on which a film is deposited in each of the film deposition portions into a roll in another unwinding/winding portion.

However, the multilayer film formation method according to the first aspect of the invention can also be implemented as a form wherein, the substrate being a sheet substrate, the step of providing the film deposition apparatus includes preparing a film deposition apparatus having substrate accumulation devices as the supply/recovery portions, and each of the transfer and film deposition steps includes feeding the substrates stocked in one accumulation device, and accumulating substrates on which a film is deposited in each of the film deposition portions in another accumulation device.

The invention is also directed to a film deposition apparatus for implementing the multilayer film formation method described above. That is, a film deposition apparatus according to a second aspect of the invention includes a transfer device that can continuously transfer the substrate at a predetermined transfer speed in both forward and reverse directions, first and second supply/recovery portions, disposed at first and second ends of a transfer path of the substrate, that can supply and recover the substrate, first and second film deposition portions, disposed along the transfer path of the substrate, in communication with each other via slits through which the substrate can pass, a gas supply unit for individually supplying raw material gas to the first and second film deposition portions, and a vacuum evacuation unit for individually evacuating the first and second film deposition portions, wherein the gas supply unit includes a unit that switches between a first gas supply mode, whereby first and second raw material gases with mutually similar compositions are simultaneously supplied to the first and second film deposition portions, and a second gas supply mode, whereby third raw material gases with a composition differing from those of the first and second raw material gases, and whose compositions are essentially the same as each other, are supplied to the first and second film deposition portions.

In a preferable form of the film deposition apparatus according to the second aspect of the invention, the gas supply unit includes first and second gas supply pipes that supply raw material gas to the first and second film deposition portions, first and second branch pipe groups connected to the first and second gas supply pipes respectively, a multiple of gas supply sources connected in parallel for each gas type to the first and second branch pipe groups, a flow control unit disposed on each branch pipe of the first and second branch pipe groups, and gas supply valves that can individually open and close each branch pipe as the switching unit.

According to the heretofore described configuration, it is possible to use a common gas supply source for a kind of gas common to the first and second raw material gases, and furthermore, for a kind of gas (for example, a main gas) common to that and the third raw material gas, or of which only the concentration differs, and by adding to that gas supply source a gas supply source corresponding to another kind of gas (for example, an added constituent), it is possible to limit the number of gas supply sources to the minimum necessary, and it is possible to change the gas supply sources easily.

In the film deposition apparatus according to the second aspect of the invention, it is preferable that the substrate is an elongated, band-like flexible substrate, the first and second supply/recovery portions include first and second core drive devices for unwinding the substrate from a roll and winding the substrate into a roll, and the transfer device includes a first feed roller disposed between the first film deposition portion and first core drive device, a second feed roller disposed between the second film deposition portion and second core drive device, a first motor that drives the first feed roller, and a second motor that drives the second feed roller, wherein each of the motors can rotate in both forward and reverse directions, and the rotation speed is variable.

According to the heretofore described configuration, the multilayer film formation method according to the first aspect of the invention can be implemented as a reciprocal film deposition process using a roll-to-roll technique, and also, it is possible to configure the multilayer film deposition apparatus with a small number of film deposition portions in comparison with the heretofore known stepped film deposition type, and it is possible to reduce the scale of the device.

In the film deposition apparatus according to the second aspect of the invention, it is preferable that the transfer device is such that the rotation axis of each of the first and second core drive devices and the first and second feed rollers is oriented in a perpendicular direction so that film deposition is possible while transferring the substrate in a vertical position in the horizontal direction.

With the film deposition apparatus according to the second aspect of the invention, the point that it is possible to configure the film deposition apparatus with a small number of film deposition portions in comparison with the heretofore known stepped film deposition type, and possible to reduce the scale of the device, is as already described, but as there is a small number of film deposition portions, the transfer span between the feed rollers (or guide rollers) at either side of the film deposition section is reduced, and the occurrence of substrate drooping or tensile wrinkling due to the weight of the substrate is suppressed even with a device configuration wherein the substrate is transferred in a vertical position in the horizontal direction, which, coupled with the characteristic that it is difficult for the substrate surface to become contaminated, is advantageous in implementing a good film deposition.

As heretofore described, the multilayer film formation method and film deposition apparatus used with the method according to the invention can equalize the formation process of a multilayer film, such as a thin film photovoltaic conversion element, including a multiple of layers of differing thickness, and as the transfer speed variation range is narrowed, the burden on the device is reduced and the fluctuation in thickness caused by the transfer speed control accuracy is suppressed, which is also advantageous in stabilizing product quality. Moreover, it is possible to suppress an increase in size of the apparatus and realize a low cost with a comparatively simple apparatus configuration, as well as which, it is possible to maintain the versatility of the apparatus, and the apparatus can be applied to the formation of various multilayer films.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a schematic plan sectional view showing a film deposition apparatus of a first embodiment that implements a multilayer film formation method according to the invention;

FIG. 2 is a schematic plan sectional view showing a film deposition apparatus of a second embodiment that implements the multilayer film formation method according to the invention;

FIG. 3 is a main portion enlarged view showing one electrode pair;

FIG. 4 is a schematic sectional view showing a layered structure of a multilayer film of the first embodiment that can be formed with the method of the invention;

FIG. 5 is a schematic sectional view showing a layered structure of a multilayer film of the second embodiment that can be formed with the method of the invention; and

FIG. 6 is a diagram showing a gas supply system and vacuum evacuation system of the film deposition apparatus of the first embodiment according to the invention.

### DETAILED DESCRIPTION OF THE INVENTION

Hereafter, a detailed description will be given, referring to the drawings, of embodiments of the invention. Within the description, a description of identical or corresponding configurations in each embodiment may be omitted by attaching the same or corresponding reference numerals or characters.

### First Embodiment

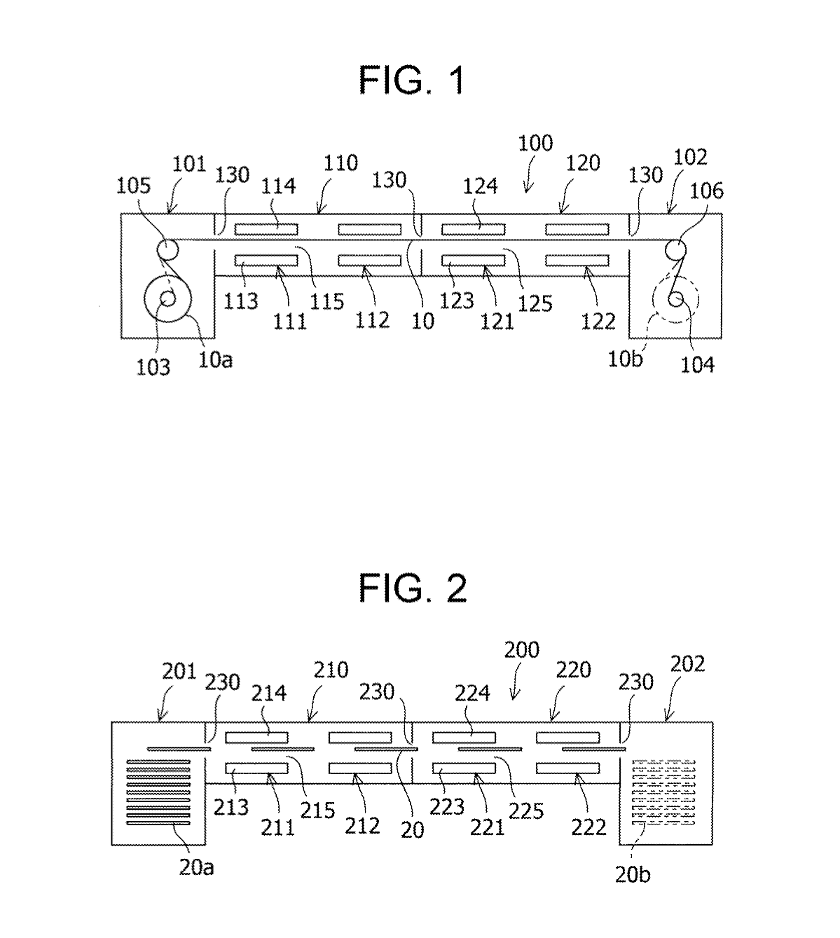

FIG. 1 shows a film deposition apparatus 100 of a first embodiment that implements a multilayer film formation method according to the invention. The film deposition apparatus 100 includes a pair of a first and second transfer chamber (a supply/recovery portion) 101 and 102 disposed one at either end in a longitudinal direction, and two film deposition chambers 110 and 120, a first and a second, disposed in-line between the first and second transfer chambers 101 and 102, and is configured in such a way that, while a substrate 10 is transferred in-line from one of the transfer chambers 101 and 102 toward the other through each of the film deposition chambers 110 and 120, thin film layers are formed by being stacked on the surface of the substrate 10 by a gas-phase chemical reaction at a parallel plate type of electrode pairs 111 and 112 and electrode pairs 121 and 122 arranged in parallel in the film deposition chambers 110 and 120 respectively.

The substrate 10 of the first embodiment is formed from a band-like, flexible substrate made of plastic film, or the like. Core drive devices (103 and 104) for unwinding the flexible substrate 10 wound in a roll form around the periphery of one of the cores 103 (104) and winding it on to the other core 104 (103), and feed rollers 105 and 106 rotationally driven in synchronization in order to transfer the flexible substrate 10 between the cores 103 and 104 at a predetermined transfer speed and transfer tension, are disposed in the transfer chambers 101 and 102, and furthermore, although omitted from the drawing, a tension roller for detecting the tension of the substrate 10, a guide roller that guides the flexible substrate 10 on a transfer path, and the like, are provided. Apart from these, an end portion position control roller that controls the width direction position of the substrate 10, and a grip roller that grips the width direction end portion of the flexible substrate 10, may also be annexed.

In the film deposition apparatus 100, each of the cores 103 and 104 and feed rollers 105 and 106 is driven by a reversible motor so that it is possible to transfer the substrate 10 in both directions between the transfer chambers (the supply/recovery portion) 101 and 102 at either side, and implement a reciprocating film deposition step. At this time, by carrying out speed control with the motor of the feeder roll (106) positioned on the downstream side of the transfer direction as a master, carrying out torque control, with the motor of the feeder roll (105) positioned on the upstream side of the transfer direction as a slave, in such a way that the transfer tension of the substrate 10 is kept constant, and carrying out torque control of the motors of each of the cores 103 and 104 in such a way that unwinding and winding tensions are kept constant, it is possible to transfer the substrate 10 continuously at the predetermined transfer speed and transfer tension. Speed control and torque control in a variable speed operation of the motors of the feed rollers 105 and 106 can be implemented by an inverter control. However, when the speed variation range is small, implementation is also possible with a closed loop voltage control. Also, it is also possible to use a DC brushless motor.

In the following description, for the sake of convenience, the direction from the first transfer chamber 101 toward the second transfer chamber 102 is taken to be the forward direction. Also, in the example shown in the drawing, each of the film deposition chambers 110 and 120 and electrode pairs 111, 112, 121, and 122 are symmetrically disposed in the longitudinal direction in the same number and with the same form, but the number of electrode pairs installed, the electrode area, and the like, may also be disposed asymmetrically in the longitudinal direction. However, in terms of freedom and applicability in the various film deposition steps, the kind of symmetrical disposition of the example shown in the drawing is advantageous. Also, although the film deposition apparatus 100 is such that all of the rotation axes of the cores 103 and 104, feeder rollers 105 and 106, tension roller, and the like, are oriented in a perpendicular direction so that film deposition is possible while transferring the substrate 10 in a vertical position in the horizontal direction, the transfer position and transfer direction are not limited to this. For example, it is also possible to configure the apparatus so as to transfer the substrate 10 in a horizontal position in the horizontal direction or up-down direction.

Although, for example, a highly heat resistant polyimide film (PI) is preferred as the flexible substrate 10, it is also possible to use another plastic film, such as polyetherimide (PEI), polyethernitrile (PEN), polyethersulfone (PES), polyamide (PA), polyamide imide (PAI), polyetheretherketone (PEEK), or polyethylene-telephthalate (PET), and furthermore, it is also possible to use a metal foil such as aluminum or stainless steel.

Although the thickness of the flexible substrate 10 is not particularly limited, a thin substrate is advantageous in terms of being able to reduce material costs. However, as processing costs increase depending on the material, and it may happen that deformation due to stress increases and transfer becomes difficult, when the substrate is too thin, it is necessary to select a thickness appropriate to the material. Although a polyimide film with a width of 500 mm and a thickness of 50 μm is used as the flexible substrate 10 in working examples to be described hereafter, in terms of device cost and manufacturing cost, it is desirable that the width of the flexible substrate 10 is as large as possible as long as film uniformity can be obtained.

While each of the film deposition chambers 110 and 120 and each of the transfer chambers 101 and 102 are hermetically joined to each other, configuring as a whole a common chamber (a common vacuum chamber), each of them is separated off by a partition, and the conductance between chambers is reduced. Although slits 130 are provided penetrating each partition enabling the substrate 10 to pass through, and the chambers are in communication with each other via the relevant slit 130, each chamber is individually evacuated, and the vacuum of each chamber is kept approximately the same, meaning that the circulation of gas between chambers is suppressed. The slits 130 are formed to a width of, for example, 5 mm in a direction perpendicular to the substrate 10 with the width of 500 mm, but can be made narrower when the transfer accuracy of the substrate 10 is high. However, as it is necessary to use a high cost gasket, or the like, in order to suppress the interdiffusion of gas when the film deposition chambers have differing pressures, it is taken that the pressures are the same.

The electrode pairs 111 and 112 and electrode pairs 121 and 122 disposed inside the film deposition chambers 110 and 120 respectively, each configuring a capacitively coupled plasma CVD apparatus, are configured of cathodes (high frequency electrodes) 113 and 123 and anodes (ground electrodes) 114 and 124 disposed in parallel on either side of the transfer path of the substrate 10. The cathodes 113 and 123 are connected to a high frequency power source 118 disposed in the exterior of the common chamber. In the working examples to be described hereafter, each of the electrode pairs 111, 112, 121, and 122 is configured, with respect to the substrate width of 500 mm, of parallel plate electrodes of 300 mm in the transfer direction and 500 mm in the substrate width direction.

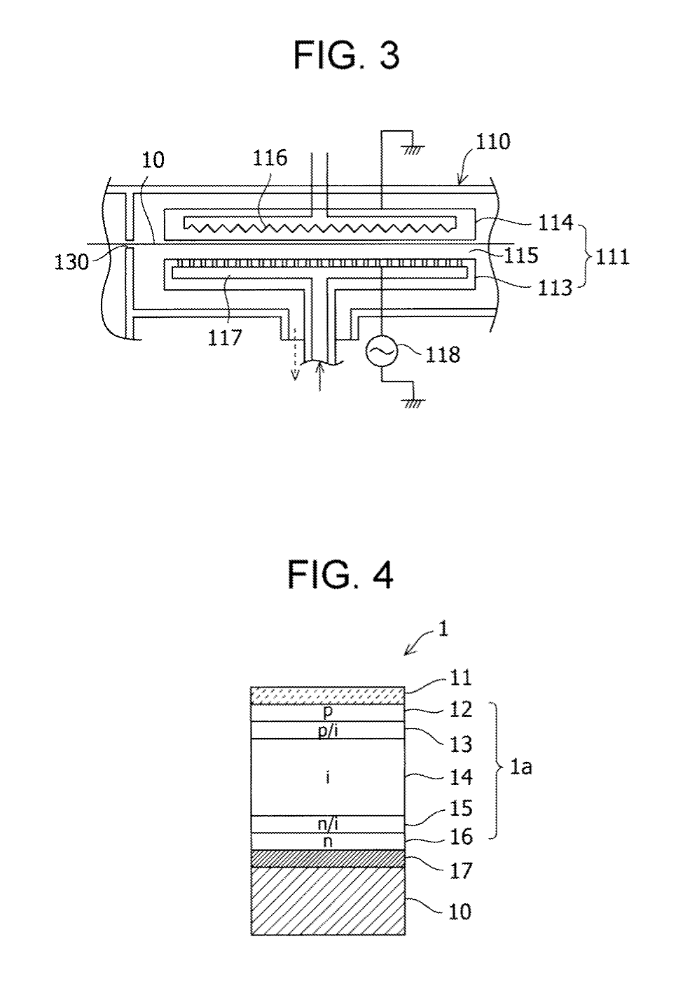

FIG. 3 shows a preferred embodiment of the electrode pair 111 configuring a plasma CVD apparatus. In FIG. 3, the cathode 113 is of a showerhead electrode structure formed from a perforated plate having a multiple of gas ejection holes on a surface thereof, and it is possible to introduce gas through the gas ejection holes of the cathode 113 into a discharge film deposition region 115 between the pair of electrodes by supplying gas from the exterior of the common chamber into a gas chamber 117 defined at the rear of the structure. Also, a heater is built into the anode 114, and the substrate 10 and discharge film deposition region 115 running along the anode 114 can be heated.

By applying a high frequency voltage between the cathode 113 and anode 114 configured as heretofore described, plasma is formed in the discharge film deposition region 115, a radical, which is a precursor of a film deposition in the plasma, diffuses and is deposited on a surface of the substrate 10, and it is possible to form a thin film. With the electrode pair 111 with this kind of showerhead electrode structure, as well as a uniform gas distribution being obtained, it is difficult for gas introduced into another film deposition region to enter the discharge film deposition region 115 owing to a gas flow occurring in the discharge film deposition region 115 between the pair of electrodes. Consequently, continuous film deposition is possible by simultaneously supplying gas into the other electrode pair 112 installed in the same film deposition chamber 110, provided that the gas is of a composition near that of the gas of the electrode pair 111, and furthermore, it may be possible to omit the partition (the slit 130) between the film deposition chambers 110 and 120 by raising the gas pressure at a time of film deposition.

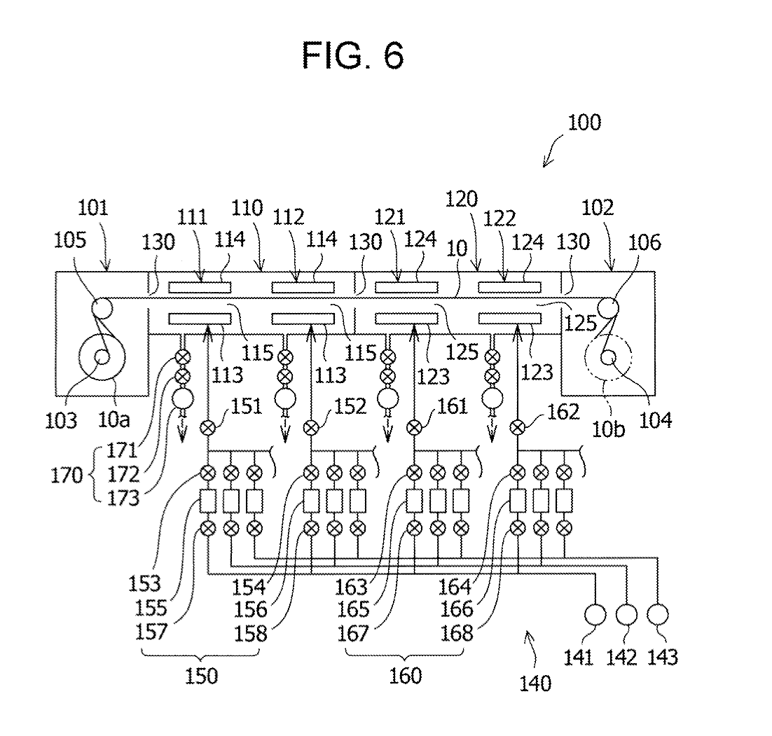

FIG. 6 shows a gas supply system 140 and vacuum evacuation system 170 of the film deposition apparatus 100 of the first embodiment. The gas supply system 140 for discharge film deposition regions 115, 115, 125, and 125 of the electrode pairs 111, 112, 121, and 122 disposed inside the film deposition chambers 110 and 120 is configured of a multiple of gas supply sources 141, 142, 143, and so on, formed from gas tanks, or the like, that store raw material gas used in film deposition, and of first and second flow control portions 150 and 160.

The flow control portions 150 and 160 are of a configuration which is a combination of mass flow controllers 155, 156, 165, and 166 corresponding to the gas supply sources 141, 142, 143, and so on, and gas supply valves 153, 154, 157, 158, 163, 164, 167, and 168 before and after the mass flow controllers, and are connected to the gas chamber (117) of each electrode pair 111, 112, 121, and 122 via on-off valves 151, 152, 161, and 162. The vacuum evacuation system 170 is configured of a vacuum pump 173 connected to each film deposition chamber 110 and 120 via an on-off valve 171 and pressure control valve 172, and is disposed for each of the electrode pairs 111, 112, 121, and 122.

According to the heretofore described configuration, by selectively opening only the gas supply valves 153, 154, 157, 158, 163, 164, 167, or 168 on the pipes of the gas supply sources 141, 142, or 143 corresponding to the kinds of gas to be introduced into each of the electrode pairs 111, 112, 121, and 122, it is possible to introduce the desired raw material gas at a predetermined mixture ratio, while controlling the flow, into each of the electrode pairs 111, 112, 121, and 122.

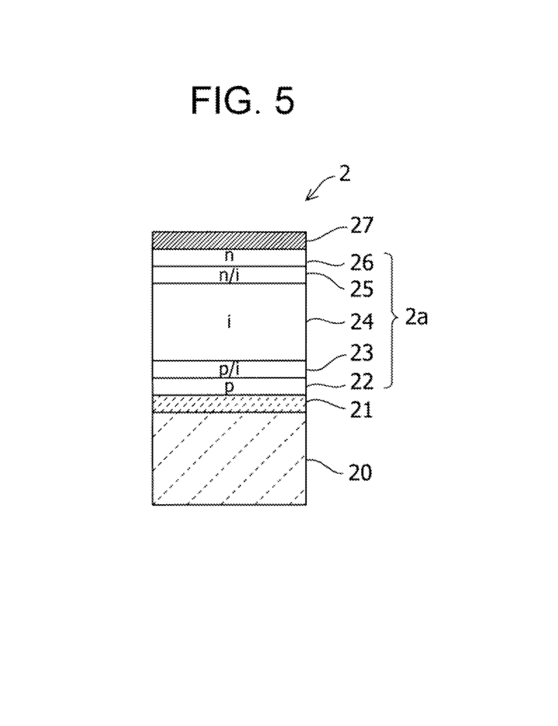

Next, FIG. 4 shows a layered structure of a substrate type thin film photovoltaic conversion element 1 (a thin film photovoltaic cell) as an example of a multilayer film that can be formed with the method of the invention using the film deposition apparatus 100 of the first embodiment. The thin film photovoltaic conversion element 1 is such that a metal electrode layer 17, an n-layer 16, an n/i interface layer 15, an i-layer 14, a p/i interface layer 13, a p-layer 12, and a transparent electrode layer 11 are sequentially stacked on the substrate 10, and FIG. 4 shows an example thereof as a single cell including one p-i-n junction structure 1a.

In the heretofore described kind of thin film photovoltaic conversion element 1, the compositions of the p/i interface layer 13 and n/i interface layer 15 are nearer the compositions of the p-layer 12 and n-layer 16, which are dope layers adjacent to the respective interface layers, than to that of the i-layer 14, which is an intrinsic semiconductor layer. In the case of an amorphous silicon (a-Si) semiconductor film, boron (B) is added as a p-type dopant and phosphorus (P) as an n-type dopant, and a doping gas such as diborane (B₂H₆) or phosphine (PH₃) including boron or phosphorus is added to silane (SiH₄), which is a main gas, or hydrogen, which is a diluent gas, but a gas wherein the various doping gases are mixed at differing low concentrations is used at the interface layer thereof too. For this reason, even when there is a certain amount of interdiffusion of gas (even though an intermediate region is formed), there is little effect in terms of function.

Moreover, the thickness of each of the interface layers (13 and 15) and dope layers (12 and 16) is extremely small at a few percent of the i-layer (14), and even when taking into consideration the depositing speed during film deposition, the film deposition time of each one is short in comparison with that of the i-layer (14). Therefore, by simultaneously supplying gases of differing compositions to the two film deposition chambers 110 and 120 of the film deposition apparatus 100, and simultaneously and continuously depositing each interface layer (13 and 15) and the dope layers (12 and 16) adjacent thereto in one transfer and film deposition step each, it is possible to make the transfer speed in the film deposition steps one half of that when depositing individually, and it is possible to keep the difference with the transfer speed in the transfer and film deposition step of the i-layer (14), that is, the transfer speed variation range, small.

For example, Table 1 shows the thickness (nm), depositing speed (nm/sec), film deposition time (sec), and transfer speed (mm/sec) of each layer configuring the p-i-n junction structure 1a of the substrate type thin film photovoltaic conversion element 1 shown in FIG. 4, wherein the film deposition time of the other layers with respect to 800 (sec) for the i-layer is 120 (sec), which is only 15% of the time for the i-layer.

TABLE 1

| | | | | | Transfer Speed | |
|---|---|---|---|---|---|---|
| | | | De- | | (mm/sec) | |
| | | | positing | Film | Com- | |
| Reference | | Thickness | Speed | Deposition | parison | Working |
| Number | Layer | (nm) | (nm/sec) | Time (sec) | Example | Example |
| 16 | n | 12 | 0.1 | 120 | 10 | 5 |
| 15 | n/i | 12 | 0.1 | 120 | 10 | 5 |
| 14 | i | 400 | 0.5 | 800 | 1.5 | 1.5 |
| 13 | p/i | 12 | 0.1 | 120 | 10 | 5 |
| 12 | p | 12 | 0.1 | 120 | 10 | 5 |

| | | |
|---|---|---|
| Thickness Fluctuation (%) | 20% | 4% |

Supposing, provisionally, that each of the layers (12, 13, 15, and 16) is deposited individually, the transfer speed in each transfer and film deposition step is set at 10 (mm/sec), which is 6.7 times the transfer speed of 1.5 (mm/sec) in the transfer and film deposition step of the i-layer (14), as shown in the comparison example of Table 1. That is, when taking the transfer speed in the transfer and film deposition step of each of the layers (12, 13, 15, and 16) as a rating, it is necessary to implement the film deposition step at a transfer speed one sixth or less of the rating. In this case, when the fluctuation in the transfer speed is 5% of full scale, the fluctuation in thickness when depositing the i-layer (14) is in the order of 20%.

As opposed to this, as shown in Working Example 1 of Table 1, when simultaneously depositing each interface layer (13 and 15) and the dope layers (12 and 16) adjacent thereto in one transfer and film deposition step each, the transfer speed in the transfer and film deposition steps is 5 (mm/sec), which is 3.3 times the transfer speed of 1.5 (mm/sec) in the transfer and film deposition step of the i-layer 14, and the transfer speed variation range is one half of that when depositing individually. In this case, even though the fluctuation in the transfer speed is 5% of full scale, in the same way as heretofore described, the fluctuation in thickness is in the order of only 4%.

Furthermore, when implementing the transfer and film deposition step of the i-layer (14), which has a large thickness, divided into two or three transfer and film deposition steps, as shown in Working Example 2 or 4 to be described hereafter, the transfer speed in each transfer and film deposition step of the i-layer (14) can be set at 3 to 4.5 (mm/sec), in which case, the transfer speed variation range is reduced to 1.67 to 1.11 times. Also, in a practical thin film photovoltaic conversion element to be described hereafter, the p-layer is deposited divided into two layers, with the conditions changed, so it can be said that in this kind of case the fluctuation in thickness can be further reduced.

Next, a description will be given of specific transfer and film deposition steps forming in layers the p-i-n junction structure 1a (the photovoltaic conversion layer) of the substrate type thin film photovoltaic conversion element 1 shown in FIG. 4, using the film deposition apparatus 100 of the first embodiment shown in FIG. 1. In this case, the metal electrode layer 17 formed from silver (Ag), aluminum (Al), or the like, has already been formed on the substrate 10 in a previous film deposition step, and the photovoltaic conversion layer is formed stacked thereupon. When continuously depositing each interface layer (13 and 15) and the dope layers (12 and 16) adjacent thereto in the same transfer and film deposition step, as in Working Example 1, the deposition of the p-i-n junction structure 1a includes the following three kinds of transfer and film deposition step.

First Transfer and Film Deposition Step:

Firstly, while the substrate 10 on which the metal electrode layer 17 has been formed is unwound from a roll 10a in the first transfer chamber 101, and transferred at a transfer speed of 5 (mm/sec) in the forward direction toward the second transfer chamber 102, a mixed gas to which phosphine (PH₃) is added as an n-type doping gas, using, for example, silane (SiH₄) and carbon dioxide (CO₂) as main gases and hydrogen (H₂) as a diluent gas, is supplied to each discharge film deposition region 115 of the first film deposition chamber 110, at the same time as which, the main gases are supplied to each discharge film deposition region 125 of the second film deposition chamber 120 without adding a doping gas, with the amount of carbon dioxide reduced and diluted to a low concentration, the n-layer 16 of an amorphous silicon oxide (a-SiO) series is formed in the first film deposition chamber 110 using a plasma CVD method, and the n/i interface layer 15 is formed in the second film deposition chamber 120 stacked on the n-layer 16 deposited immediately before. In the final stage of this kind of transfer and film deposition step, that is, at the terminal portion of the substrate 10, with the substrate 10 still moving or in a condition in which the substrate 10 is stopped, emission from a doping gas member in the next process is suppressed by implementing a film deposition step for a predetermined time in a region of the substrate 10 in which no film is deposited, without adding a doping gas, and covering at least one portion of the constituent members in each film deposition chamber.

Second Transfer and Film Deposition Step:

Next, while the substrate 10 on which the n-layer 16 and n/i interface layer 15 are formed by being stacked on the metal electrode layer 17, and which is wound in the second transfer chamber 102 as a roll 10b, is unwound from the roll 10b and transferred at a transfer speed of 1.5 (mm/sec) in the reverse direction toward the first transfer chamber 101, silane (SiH₄) diluted with hydrogen is supplied to each discharge film deposition region 115 and 125 of the first and second film deposition chambers 110 and 120, and the i-layer 14 of amorphous silicon (a-Si) is deposited using a plasma CVD method.

Third Transfer and Film Deposition Step:

Next, while the substrate 10 on which the n-layer 16, n/i interface layer 15, and i-layer 14 are formed by being stacked on the metal electrode layer 17, and which is wound in the first transfer chamber 101 as the roll 10a, is unwound from the roll 10a and transferred at a transfer speed of 5 (mm/sec) in the forward direction toward the second transfer chamber 102, a mixed gas diluted to a low concentration, and to which a small amount of diborane (B₂H₆) is added as a p-type doping gas, using, for example, silane (SiH₄) and carbon dioxide (CO₂) as main gases and hydrogen (H₂) as a diluent gas, is supplied to each discharge film deposition region 115 of the first film deposition chamber 110, at the same time as which, a mixed gas using silane (SiH₄) and carbon dioxide (CO₂) as main gases and hydrogen (H₂) as a diluent gas, to which diborane (B₂H₆) is added as a p-type doping gas, and wherein the concentration of the main gases and the amount of doping gas added are raised higher than those previously described, is supplied to each discharge film deposition region 125 of the second film deposition chamber 120, the p/i interface layer 13 of an amorphous silicon oxide (a-SiO) series is formed in the first film deposition chamber 110 using a plasma CVD method, the p-layer 12 is formed in the second film deposition chamber 120 stacked on the p/i interface layer 13 deposited immediately before, and the substrate 10 is wound onto the roll 10b in the second transfer chamber 102.

In the heretofore described third transfer and film deposition step, it is also possible to gradually raise the amount of the p-type doping gas (B₂H₆) added, and gradually reduce the concentration of the carbon dioxide (CO₂), in the discharge film deposition regions 125 corresponding to each of the electrode pairs 121 and 122 in the second film deposition chamber 120, in which cases, the three kinds of layer are continuously formed by being stacked to a predetermined thickness corresponding to each one thereof in the third transfer and film deposition step. Also, when dividing the implementation of the i-layer 14 deposition in two as previously described, it is sufficient to implement the second transfer and film deposition step twice while reciprocally transferring the substrate 10 at a transfer speed of 3 (mm/sec) in both the forward and reverse directions.

When implementing the gas supply in the first to third transfer and film deposition steps with the gas supply system 140 shown in FIG. 6 of the film deposition apparatus 100 of the first embodiment, although only the gas supply sources 141 to 143 of three systems are shown in FIG. 6, the same kind of gas supply source is prepared for five systems of, for example, silane (SiH₄), carbon dioxide (CO₂), hydrogen (H₂), phosphine (PH₃), and diborane (B₂H₆).

Then, in each of the first to third transfer and film deposition steps, by selectively opening the gas supply valves 153, 154, 157, 158, 163, 164, 167, or 168 corresponding to the kinds of gas used in each of the first and second film deposition chambers 110 and 120, and implementing flow control with the corresponding mass flow controllers 155, 156, 165, or 166, it is possible to switch the kind, concentration, and mixture ratio of the raw material gas. It is also possible to prepare a raw material gas diluted to a predetermined degree of dilution in each gas supply source.

In the first embodiment, a description has been given of the transfer and film deposition steps of forming in layers the p-i-n junction structure 1a of the substrate type thin film photovoltaic conversion element 1, but it is also possible to use the film deposition apparatus 100 for the previous step (primary film deposition step) of forming the metal electrode layer 17 on the substrate 10, or for depositing the transparent electrode layer 11 on the p-i-n junction structure 1a. However, as there is a laser scribing step, or the like, of dividing the metal electrode layer 17 into a multiple of unit cells after the primary film deposition step, the substrate 10 (roll) is temporarily removed from the transfer chamber 101 or 102. Also, in the substrate type thin film photovoltaic conversion element 1, it may be that a metal electrode layer for a series connection is formed on the rear surface (the lower surface in FIG. 4) of the substrate 10, and it is also possible to use the film deposition apparatus 100 in the way heretofore described in a film deposition step of the metal electrode layer.

Also, in the embodiment, a description has been given of a case in which the n-layer and n/i interface layer, and p/i interface layer and p-layer, are deposited continuously in the same transfer and film deposition step, but it is also acceptable to implement the transfer and film deposition step for only the n-layer and n/i interface layer, or only the p/i interface layer and p-layer. Also, apart from an amorphous silicon (a-Si) or amorphous silicon oxide (a-SiO), it is possible to use a heretofore known silicon series material, such as an amorphous silicon carbide (a-SiC) or amorphous silicon nitride (a-SiN), as the silicon series material configuring the p-i-n junction structure, and the material may also be a microcrystalline silicon (μc-Si) thin film, a microcrystalline silicon thin film including an amorphous phase, or the like.

Furthermore, in the embodiment, an example of the thin film photovoltaic conversion element 1 as a single cell including the one p-i-n junction structure 1a is shown, but the thin film photovoltaic conversion element 1 may also be a multi-junction structure, such as a two-layered tandem in which two p-i-n junction structures are stacked, or a triple cell in which three p-i-n junction structures are stacked. In these cases, as the first to third transfer and film deposition steps are repeated, changing the composition of the raw material gas and the film deposition conditions as necessary, it can be said that the more junction structures there are, the greater the merit of the multilayer film formation method according to the invention with respect to simplifying the manufacturing process, reducing the burden on the device, stabilizing product quality, and the like.

### Second Embodiment

FIG. 2 shows a film deposition apparatus 200 of a second embodiment that implements the multilayer film formation method according to the invention. The film deposition apparatus 200, in order to implement the same kind of reciprocal transfer and film deposition step as in the first embodiment while a sheet substrate 20, such as a glass substrate, is transferred in-line, includes a pair of a first and second transfer chamber (a supply/recovery portion) 201 and 202 disposed one at either end in a longitudinal direction, and two film deposition chambers 210 and 220, a first and a second, disposed in-line between the first and second transfer chambers 201 and 202.

In the film deposition apparatus 200, although the configuration of parallel plate type electrode pairs 211 and 212 and electrode pairs 221 and 222 arranged in parallel in the film deposition chambers 210 and 220 respectively is the same as in the first embodiment, an unshown transfer device formed from a conveyor roller, a conveyor belt, or the like, that conveys the substrate 20 by gripping the width direction end portions thereof, is provided in each film deposition chamber 210 and 220 in order to transfer the sheet substrate 20 in-line at a predetermined pitch along the transfer path.

Furthermore, each transfer chamber 201 and 202 is configured as an accumulation device that stocks a multiple of the sheet substrates 20 (20a, 20b) in a stacked condition, and that can supply the stocked substrates 20 by feeding thereof one by one to the transfer device (transfer path). Each transfer chamber 201 and 202 (the accumulation devices) and the transfer device may be configured in such a way as to stock the sheet substrates in a condition in which they are held individually in a holder (carrier), and to be able to carry out transfer and film deposition.

Also, a mechanism that changes the transfer direction of the substrate 20 may also be included partway along the linear transfer path. Furthermore, it is also possible to configure in such a way that, circulating the terminus (the transfer chamber 202) of the transfer path to the beginning (the transfer chamber 201), the substrates 20 that have finished one transfer and film deposition step are accumulated in the transfer chamber 201 in order that the next transfer and film deposition step is implemented in the same transfer direction.

Also, in the example shown in the drawing, each of the film deposition chambers 210 and 220 and electrode pairs 211, 212, 221, and 222 are symmetrically disposed in the longitudinal direction in the same number and with the same form but, as in the case of the first embodiment, the number of electrode pairs installed, the electrode area, and the like, may also be disposed asymmetrically in the longitudinal direction. Furthermore, the film deposition apparatus 200, as well as being configured so as to carry out deposition while transferring the substrate 20 in a vertical position in the horizontal direction, may be configured so as to carry out deposition while transferring the substrate 20 in a horizontal position in the horizontal direction or up-down direction.

As it is clear from the drawing that it is also possible to implement the same kinds of transfer and film deposition steps with the film deposition apparatus 200 configured as heretofore described as with the film deposition apparatus 100 of the first embodiment, a detailed description will be omitted here. Also, the film deposition apparatus 200 of the second embodiment can be preferably used, other than for the substrate type thin film photovoltaic conversion element 1 shown in FIG. 4, in a transfer and film deposition step of a superstrate type thin film photovoltaic conversion element using a transparent sheet substrate of glass or the like.

FIG. 5 shows a layered structure of a superstrate type thin film photovoltaic conversion element 2 (a thin film photovoltaic cell) that can be formed with the method of the invention using the film deposition apparatus 200 of the second embodiment. In FIG. 5, the thin film photovoltaic conversion element 2 is such that a transparent electrode layer 21, a p-layer 22, a p/i interface layer 23, an i-layer 24, an n/i interface layer 25, an n-layer 26, and a metal electrode layer 27 are sequentially stacked on the transparent substrate 20, and FIG. 5 shows an example thereof as a single cell including one p-i-n junction structure 2a.

As the superstrate type thin film photovoltaic conversion element 2 is such that the orientation of the p-i-n junction structure 2a with respect to the substrate 20 is vertically the reverse of that of the substrate type, the film deposition order is reversed, but the point that each interface layer (23 and 25) and the dope layers (22 and 26) adjacent thereto are continuously deposited in the same transfer and film deposition step, and the i-layer 24 is deposited in a separate transfer and film deposition step, is the same as in the first embodiment.

That is, in a first transfer and film deposition step, while the substrate 20 on which the transparent electrode layer 21 has been formed is transferred in the forward direction from the first transfer chamber 201 toward the second transfer chamber 202, the p-layer 22 and p/i interface layer 23 are continuously formed by being stacked on the transparent electrode layer 21, then, in a second transfer and film deposition step, while the substrate 20 is transferred in the reverse direction, the i-layer 24 is formed on the p/i interface layer 23, and furthermore, in a third transfer and film deposition step, while the substrate 20 is transferred in the forward direction again, the n/i interface layer 25 and n-layer 26 are continuously formed by being stacked on the i-layer 24.

Next, a description will be given of each working example according to the invention. Although the following working examples are basically examples of implementing the p-i-n junction structure transfer and film deposition steps based on the first embodiment, it will be easily understood that they can also become working examples of the second embodiment by adding the heretofore described kinds of change.

Working Example 2:

In Working Example 2 shown in Table 2, the following kinds of two reciprocal transfer and film deposition steps 1 to 4 are implemented using the film deposition apparatus 100 wherein the length of the transfer section (film deposition region) of the two film deposition chambers 110 and 120 combined is 2m, and a multilayer film of a p-i-n junction structure (a photovoltaic conversion layer) is formed on a substrate on which a metal electrode layer and a transparent electrode layer are formed by being stacked.

TABLE 2

| | Film | Film Deposition Time (sec) | | | | Transfer Speed (mm/sec) | | | |
|---|---|---|---|---|---|---|---|---|---|
| | Deposition | Step | | | | Step | | | |
| Layer | Time (sec) | 1 | 2 | 3 | 4 | 1 | 2 | 3 | 4 |
| N | 120 | 240 | | | | 8.4 | | | |
| n/i | 120 | | | | | | | | |
| I | 800 | | 400 | 400 | | | 5.0 | 5.0 | |
| p/i | 120 | | | | 240 | | | | 8.4 |
| p1 | 60 | | | | | | | | |
| p2 | 60 | | | | | | | | |

2.1: Transfer and Film Deposition Step 1.

While transferring the substrate 10 in the forward direction at a transfer speed of 8.4 mm/sec., an a-SiO series n-layer is deposited in the first film deposition chamber 110 with a main gas SiH₄ at 5 ml/min., a hydrogen degree of dilution (H₂/SiH₄) of 10 times, an amount of doping gas added (PH₃/SiH₄) at 1%, and an amount of carbon dioxide added (CO₂/SiH₄) at 1 time, and an n/i layer is deposited in the second film deposition chamber 120 with the main gas SiH₄ at 5 ml/min., a hydrogen degree of dilution (H₂/SiH₄) of 25 times, no doping gas added, and the amount of carbon dioxide added (CO₂/SiH₄) at 0.3 times.

2.2: Transfer and Film Deposition Step 2.

While transferring the substrate 10 in the reverse direction at a transfer speed of 5.0 mm/sec., one half of an a-SiO i-layer is deposited in the first and second film deposition chambers 110 and 120, with the main gas SiH₄ at 20 ml/min., and a hydrogen degree of dilution (H₂/SiH₄) of 10 times.

2.3: Transfer and Film Deposition Step 3.

While transferring the substrate 10 in the forward direction at the same transfer speed of 5.0 mm/sec. as in Step 2, the remaining one half of the a-Si i-layer is deposited under the same gas conditions as in Step 2.

2.4: Transfer and Film Deposition Step 4.

While transferring the substrate 10 in the reverse direction at a transfer speed of 8.4 mm/sec., a p/i layer is deposited in the second film deposition chamber 120 with the main gas SiH₄ at 5 ml/min., a hydrogen degree of dilution (H₂/SiH₄) of 25 times, the amount of doping gas added (B₂H₆/SiH₄) at 100 ppm, and the amount of carbon dioxide added (CO₂/SiH₄) at 0.4 times, an a-SiO series p1 layer is deposited at the second electrode pair 112 of the first film deposition chamber 110 with the main gas SiH₄ at 5 ml/min., a hydrogen degree of dilution (H₂/SiH₄) of 20 times, the amount of doping gas added (B₂H₆/SiH₄) at 1%, and the amount of carbon dioxide added (CO₂/SiH₄) at 1 time, and an a-SiO series p2 layer is deposited at the first electrode pair 111 of the first film deposition chamber 110 with the main gas SiH₄ at 5 ml/min., a hydrogen degree of dilution (H₂/SiH₄) of 20 times, the amount of doping gas added (B₂H₆/SiH₄) at 2%, and the amount of carbon dioxide added (CO₂/SiH₄) at 1 time.

In Working Example 2, while the n-layer and n/i layer are deposited simultaneously in transfer and film deposition step 1, and the i-layer, which has the greatest thickness, is deposited divided between transfer and film deposition steps 2 and 3, the p/i layer, and the p1 layer and p2 layer which have half the thickness of the p/i layer, are deposited simultaneously in transfer and film deposition step 4. In Working Example 2, it is possible to set the transfer speed (2.5 mm/sec) of transfer and film deposition steps 2 and 3 at twice that of the transfer speed (1.25 mm/sec) in the case of depositing the i-layer in one step, and the difference with the transfer speed of the other transfer and film deposition steps 1 and 4 is reduced. Also, in transfer and film deposition step 4, the film deposition region of the film deposition apparatus 100 is divided into three regions, a one half region corresponding to the second film deposition chamber 120 and two one quarter regions corresponding to the electrode pairs 111 and 112 of the first film deposition chamber 110, and three layers are deposited simultaneously.

Working Example 3:

In Working Example 3 shown in Table 3, the following kinds of 1.5 reciprocal transfer and film deposition steps 1 to 3 are implemented using the film deposition apparatus 100 wherein the length of the transfer section (film deposition region) of the two film deposition chambers 110 and 120 combined is 2m, as in Working Example 2, and a multilayer film of a p-i-n junction structure (a photovoltaic conversion layer) is formed on a substrate on which a metal electrode layer and a transparent electrode layer are formed by being stacked.

TABLE 3

| | Film | Film Deposition Time (s) | | | Transfer Speed (mm/sec) | | |
|---|---|---|---|---|---|---|---|
| | Deposition | Step | | | Step | | |
| Layer | Time (sec) | 1 | 2 | 3 | 1 | 2 | 3 |
| N | 120 | 120 | | | 16.6 | | |
| I | 380 | | 380 | | | 5.2 | |
| p/i | 60 | | | 150 | | | 13.3 |
| p1 | 30 | | | | | | |
| p2 | 60 | | | | | | |

3.1: Transfer and Film Deposition Step 1.

While transferring the substrate 10 in the forward direction at a transfer speed of 16.6 mm/sec., an a-SiO series n-layer is deposited in the first and second film deposition chambers 110 and 120 with a main gas SiH₄ at 10 ml/min., a hydrogen degree of dilution (H₂/SiH₄) of 25 times, an amount of doping gas added (PH₃/SiH₄) at 4%, and an amount of carbon dioxide added (CO₂/SiH₄) at 0.25 times.

3.2: Transfer and Film Deposition Step 2.

While transferring the substrate 10 in the reverse direction at a transfer speed of 5.2 mm/sec., an i-layer is deposited in the first and second film deposition chambers 110 and 120, with the main gas SiH₄ at 25 ml/min., and a hydrogen degree of dilution (H₂/SiH₄) of 15 times. In Working Example 3, in compensation for an n/i layer being omitted, an extremely small amount (2 ppm) of a doping gas is added to the i-layer.

3.3: Transfer and Film Deposition Step 3.

While transferring the substrate 10 in the forward direction at a transfer speed of 13.3 mm/sec., a p/i layer is deposited in the first film deposition chamber 110 with the main gas SiH₄ at 10 ml/min., a hydrogen degree of dilution (H₂/SiH₄) of 25 times, the amount of doping gas added (B₂H₆/SiH₄) at 200 ppm, and the amount of carbon dioxide added (CO₂/SiH₄) at 0.35 times, a p1 layer is deposited at the first electrode pair 121 of the second film deposition chamber 120 with the main gas SiH₄ at 10 ml/min., a hydrogen degree of dilution (H₂/SiH₄) of 20 times, the amount of doping gas added (B₂H₆/SiH₄) at 1%, and the amount of carbon dioxide added (CO₂/SiH₄) at 2 times, and a p2 layer is deposited at the second electrode pair 122 of the second film deposition chamber 120 with the main gas SiH₄ at 10 ml/min., a hydrogen degree of dilution (H₂/SiH₄) of 20 times, the amount of doping gas added (B₂H₆/SiH₄) at 2%, and the amount of carbon dioxide added (CO₂/SiH₄) at 0.9 times.

In Working Example 3, as the thickness of the i-layer is small in comparison with the previous working examples, the number of steps is kept to three with the i-layer being deposited in one transfer and film deposition step, and a simplification of the processing steps is achieved.

In Working Example 4 shown in Table 4, the following kinds of three reciprocal transfer and film deposition steps 1 to 6 are implemented using a film deposition apparatus including three film deposition chambers whose lengths in the transfer direction are unequal, wherein two electrode pairs are arranged in parallel in a first film deposition chamber and three electrode pairs in a second film deposition chamber, three half sized electrode pairs are arranged in parallel in a third film deposition chamber, and the length of the transfer section (film deposition region) of the first to third film deposition chambers combined is 3m, and a multilayer film of a p-i-n junction structure (a photovoltaic conversion layer) is formed on a substrate on which a metal electrode layer and a transparent electrode layer are formed by being stacked.

TABLE 4

| | Film | Film Deposition Time (s) | | | | | | Transfer Speed (mm/sec) | | | | | |
|---|---|---|---|---|---|---|---|---|---|---|---|---|---|
| | Deposition | Step | | | | | | Step | | | | | |
| Layer | Time (sec) | 1 | 2 | 3 | 4 | 5 | 6 | 1 | 2 | 3 | 4 | 5 | 6 |
| N | 60 | 190 | | | | | | 15.8 | | | | | |
| N/i | 130 | | | | | | | | | | | | |
| I1 | 20 | | 120 | | | | | | 25.0 | | | | |
| I | 1,000 | | | 300 | 300 | 300 | | | | 10.0 | 10.0 | 10.0 | |
| P/i | 15 | | | | | | 160 | | | | | | 18.8 |
| P1 | 25 | | | | | | | | | | | | |
| P2 | 120 | | | | | | | | | | | | |

4.1: Transfer and Film Deposition Step 1.

While transferring a substrate in the forward direction at a transfer speed of 15.8 mm/sec., an a-SiO series n-layer is deposited in the first film deposition chamber with a main gas SiH₄ at 20 ml/min., a hydrogen degree of dilution (H₂/SiH₄) of 5 times, an amount of doping gas added (PH₃/SiH₄) at 4%, and an amount of carbon dioxide added (CO₂/SiH₄) at 1 time, and an n/i layer is deposited in the second and third film deposition chambers with the main gas SiH₄ at 20 ml/min. (10 ml/min. in each chamber), a hydrogen degree of dilution (H₂/SiH₄) of 25 times, and with no doping gas or carbon dioxide being added.

4.2: Transfer and Film Deposition Step 2.

While transferring the substrate in the reverse direction at a transfer speed of 25.0 mm/sec., a μc-Si i1 layer is deposited at second and third electrode pairs of the third film deposition chamber, with the main gas SiH₄ at 10 ml/min., and a hydrogen degree of dilution (H₂/SiH₄) of 200 times, and 10% of a μc-Si i-layer is deposited at a first electrode pair of the third film deposition chamber and in the second and first film deposition chambers, with the main gas SiH₄ at 20 ml/min., and a hydrogen degree of dilution (H₂/SiH₄) of 100 times.

4.3: Transfer and Film Deposition Step 3.

While transferring the substrate in the forward direction at a transfer speed of 10.0 mm/sec., 30% of the μc-Si i-layer is deposited in the first to third film deposition chambers, with the main gas SiH₄ at 20 ml/min., and a hydrogen degree of dilution (H₂/SiH₄) of 100 times.

4.4: Transfer and Film Deposition Step 4.

While transferring the substrate in the reverse direction at a transfer speed of 10.0 mm/sec., 30% of the μc-Si i-layer is deposited in the first to third film deposition chambers, with the main gas SiH₄ at 20 ml/min., and a hydrogen degree of dilution (H₂/SiH₄) of 100 times, in the same way as previously described.

4.5: Transfer and Film Deposition Step 5.

While transferring the substrate in the forward direction at a transfer speed of 10.0 mm/sec., the remaining 30% of the μc-Si i-layer is deposited in the first to third film deposition chambers, with the main gas SiH₄ at 20 ml/min., and a hydrogen degree of dilution (H₂/SiH₄) of 100 times, in the same way as previously described.

4.6: Transfer and Film Deposition Step 6.

While transferring the substrate in the reverse direction at a transfer speed of 18.8 mm/sec., a p/i layer is deposited at the third electrode pair of the third film deposition chamber with the main gas SiH₄ at 5 ml/min., a hydrogen degree of dilution (H₂/SiH₄) of 25 times, and the amount of doping gas added (B₂H₆/SiH₄) at 100 ppm, an a-Si p1 layer is deposited at the second and first electrode pairs of the third film deposition chamber with the main gas SiH₄ at 5 ml/min., a hydrogen degree of dilution (H₂/SiH₄) of 20 times, and the amount of doping gas added (B₂H₆/SiH₄) at 1%, and a μc-Si p2 layer is deposited in the second and first film deposition chambers with the main gas SiH₄ at 5 ml/min., a hydrogen degree of dilution (H₂/SiH₄) of 250 times, and the amount of doping gas added (B₂H₆/SiH₄) at 2%.

In Working Example 4, the n-layer and n/i layer are deposited simultaneously in transfer and film deposition step 1, 10% of the i-layer, which has the greatest thickness, and the i1 layer with relatively low concentration interposed on the n/i layer side of the i-layer, are deposited simultaneously in transfer and film deposition step 2, and furthermore, after the remaining 90% of the i-layer is deposited divided between transfer and film deposition steps 3 to 5, the p/i layer, p1 layer, and p2 layer are deposited simultaneously in transfer and film deposition step 6.

Even when comparing a photovoltaic conversion cell in which a transparent electrode layer is formed on the photovoltaic conversion layers of the p-i-n junction structure obtained from the multilayer film formation processes of Working Examples 1 to 4 with a photovoltaic conversion cell of the same structure in which a transparent electrode layer is formed on photovoltaic conversion layers of which each layer is deposited individually, as in the comparison example, no difference is observed in performance facets such as power generating efficiency, but on the contrary, it is possible to manufacture efficiently in markedly simplified transfer and film deposition steps and, by the transfer speed variation range being kept small, fluctuation in thickness is suppressed, and a stabilization of product quality can be expected.

Although a description has been given of some working examples of the invention, the invention is not limited to these, and various further kinds of modification and change are also possible based on the technological ideas of the invention.

For example, in each of the working examples, a case is shown in which a capacitively coupled plasma CVD is used for the film deposition apparatuses 100 and 200, but a surface wave plasma CVD (SWP-CVD), a catalytic CVD (Cat-CVD), or an electron cyclotron resonance plasma CVD (ECR-CVD) may also be utilized. However, a physical vapor deposition (PVD) such as sputtering, which does not have gas as a raw material, has no difficulty in continuously depositing plural layers, and is outside the scope of the invention.

The multilayer film formation method according to the invention is not limited to the manufacturing process of a thin film photovoltaic conversion element, and can also be utilized in other multilayer film manufacturing processes including a large number of layers of differing thicknesses.

It is understood that various other modifications will be apparent to and can be readily made by those skilled in the art without departing from the scope and spirit of the present invention. Accordingly, it is not intended that the scope of the claims appended hereto be limited to the description set forth above but rather that the claims be construed as encompassing all of the features of patentable novelty which reside in the present invention, including all features which would be treated as equivalents thereof by those skilled in the art to which the invention pertains.

1. A multilayer film formation method that employs gas-phase chemical reaction to form a multilayer film having at least three layers on at least one surface of a substrate using raw material gases of differing compositions, the method comprising the steps of:
providing a film formation apparatus having at least first and second film deposition portions along a transfer path of the substrate, and having a supply/recovery portion for the substrate at either end of the transfer path;
continuously transferring the substrate along the transfer path at a first speed during a first transfer and film deposition while simultaneously supplying first and second raw material gases having first and second compositions, respectively, that are mutually similar compositions to each of the first and second film deposition portions to form a plurality of stacked layers including first and second layers having said first and second compositions; and
continuously transferring the substrate along the transfer path at a second speed during a second transfer and film deposition, performed before or after the first transfer and film deposition, while supplying third raw material gases having a third composition that differs from those of the first and second raw material gases, to each of the first and second film deposition portions to form a third layer having said third composition that differs from those of the first and second layers.

2. The multilayer film formation method according to claim 1, wherein the third layer has a thickness that is greater than that of a plurality of layers that includes the first and second layers.

3. The multilayer film formation method according to claim 1, wherein the third layer has a thickness that is at least two times greater than that of a plurality of layers that includes the first and second layers, and the second transfer and film deposition that forms the third layer is implemented divided into a plurality of times.

4. The multilayer film formation method according to claim 1, wherein the first and second raw material gases include added constituents common to each other which differ in amounts, while the third raw material gases do not include the added constituents.

5. The multilayer film formation method according to claim 4, wherein the multilayer film is a thin film photovoltaic conversion element having a p-i-n junction structure, wherein the first and second layers respectively are a p-type semiconductor layer and p/i interface layer or an n-type semiconductor layer and n/i interface layer, wherein the added constituent is a doping gas corresponding respectively to each type, and wherein the third layer is an i-type semiconductor layer.

6. The multilayer film formation method according to claim 1, wherein the first and second raw material gases each comprise a main gas that is the same gas but that differs in its respective concentration, and wherein only the layer farther from the third layer is formed from raw material gasses that include added constituents, while the third raw material gases do not include said added constituents.

7. The multilayer film formation method according to claim 6, wherein the multilayer film is a thin film photovoltaic conversion element having a p-i-n junction structure, wherein the first and second layers are respectively a p-type semiconductor layer and p/i interface layer or an n-type semiconductor layer and n/i interface layer, wherein the added constituent is a doping gas corresponding respectively to each type, and wherein the third layer is an i-type semiconductor layer.

8. The multilayer film formation method according to claim 1, wherein the multilayer film is a thin film photovoltaic conversion element having a p-i-n junction structure, wherein the first and second layers respectively are a p-type semiconductor layer and p/i interface layer or an n-type semiconductor layer and n/i interface layer, and wherein the third layer is an i-type semiconductor layer.

9. The multilayer film formation method according to claim 1, wherein the first transfer and film deposition is accomplished in a plurality of first transfer and film depositions, while reciprocally transferring the substrate between the supply/recovery portions at either end of the transfer path.

10. The multilayer film formation method according to claim 9, wherein the substrate is a band-like substrate having a band structure, wherein the supply/recovery portions of the film deposition apparatus include respective unwinding/winding portions for accommodating the substrate, and wherein each of the first and second transfer and film depositions includes unwinding the substrate from a roll in one unwinding/winding portion and winding the substrate on which a film is deposited in each of the film deposition portions onto a roll in another unwinding/winding portion.

11. The multilayer film formation method according to claim 9, wherein the substrate is a sheet substrate, wherein the supply/recovery portions comprise substrate accumulation devices, and wherein each of the first and second transfer and film depositions includes feeding the substrate from one accumulation device and accumulating substrates on which a film is deposited in each of the film deposition portions in another accumulation device.

12. The multilayer film formation method according to claim 1, wherein the first and second film deposition portions respectively comprise first and second film deposition chambers in communication with each other via slits through which the substrate can pass; and at least one film deposition electrode pair arranged in parallel inside of each of respective ones of the first and second film deposition chambers.

13. The multilayer film formation method according to claim 12, at least two film deposition electrode pairs are arranged in parallel inside at least one of the first and second film deposition chambers.

14. The multilayer film formation method according to claim 1, wherein the first and second film deposition portions respectively comprise at least two film deposition electrode pairs arranged in parallel inside a common vacuum chamber.

15. A film deposition apparatus for implementing a multilayer film formation method according to claim 1, comprising:
transfer means for continuously transferring a substrate at a predetermined transfer speed in both forward and reverse directions along a transfer path of the substrate;
first and second supply/recovery portions disposed at first and second ends of the transfer path of the substrate that supply and recover the substrate;
first and second film deposition portions disposed along the transfer path of the substrate, in communication with each other via slits through which the substrate can pass;
a gas supply unit for individually supplying raw material gas to the first and second film deposition portions; and
a vacuum evacuation unit for individually evacuating the first and second film deposition portions,
wherein the gas supply unit includes a unit that switches between a first gas supply mode so that first and second raw material gases with mutually similar compositions are simultaneously supplied to the first and second film deposition portions, and a second gas supply mode so that third raw material gases having a composition differing from those of the first and second raw material gases are supplied to the first and second film deposition portions.

16. The film deposition apparatus according to claim 15, wherein the gas supply unit comprises:
first and second gas supply pipes that supply raw material gas to the first and second film deposition portions;
first and second branch pipe groups connected to the first and second gas supply pipes, respectively;
a multiple of gas supply sources connected in parallel for each gas type to the first and second branch pipe groups;
a flow control unit disposed on each branch pipe of the first and second branch pipe groups; and
gas supply valves provided on respective branch pipes that can individually open and close each branch pipe as a switching unit.

17. The film deposition apparatus according to claim 16, wherein the substrate is an elongated, band-like flexible substrate, wherein the first and second supply/recovery portions include first and second core drive devices for unwinding the substrate from a roll and winding the substrate onto a roll, wherein the transfer device includes a first feed roller disposed between the first film deposition portion and first core drive device, a second feed roller disposed between the second film deposition portion and second core drive device, a first motor that drives the first feed roller, and a second motor that drives the second feed roller, and wherein each of the first and second motors rotate in both forward and reverse directions and have a rotation speed that is variable.

18. The film deposition apparatus according to claim 17, wherein the transfer device is such that the rotation axis of each of the first and second core drive devices is oriented in a perpendicular direction so that film deposition is accomplished while transferring the substrate in a vertical position in a horizontal direction.

19. The multilayer film formation method according to claim 1, wherein the first and second film deposition portions respectively comprise at least two film deposition electrode pairs arranged inside a common vacuum chamber.
